(19) United States
(12) Patent Application Publication
(10) Pub. No.: US 2002/0003239 A1
(43) Pub. Date: Jan. 10, 2002

(54) Semiconductor structure and device including a carbon film and method of forming the same

(75) Inventors: Jamal Ramdani, Chandler, AZ (US); Lyndee L. Hilt, Chandler, AZ (US)

Correspondence Address: MOTOROLA, INC., CORPORATE LAW DEPARTMENT - #56-238, 3102 NORTH 56TH STREET, PHOENIX, AZ, 85018, US

(73) Assignee: Motorola, Inc.

(21) Appl. No.: 09/824,615

(22) Filed: Apr. 2, 2001

Related U.S. Application Data
(63) Continuation-in-part of application No. 09/607,207, filed on Jun. 28, 2000.

(51) Int. Cl. H01L 31/0328

(52) U.S. Cl. 257/190; 257/201

(57) ABSTRACT

High quality carbon layers such as diamond or diamond-like carbon (108) can be grown overlying monocrystalline substrates (102) such as large silicon wafers by forming a compliant substrate for growing the monocrystalline layers. One way to achieve the formation of a compliant substrate includes first growing an accommodating buffer layer (104) on a silicon wafer (102). The accommodating buffer layer (104) is a layer of monocrystalline oxide spaced apart from the silicon wafer (102) by an amorphous interface layer of silicon oxide (110). The amorphous interface layer (110) dissipates strain and permits the growth of a high quality monocrystalline oxide accommodating buffer layer (104).

### CROSS REFERENCE TO RELATED APPLICATIONS

The present application is a continuation-in-part of U.S. patent application Ser. No. 09/607,207 entitled “Semiconductor Structure, Semiconductor Device, Communicating Device, Integrated Circuit, and Process for Fabricating the Same”, filed Jun. 28, 2000, by the assignee hereof.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a carbon material layer.

### BACKGROUND OF THE INVENTION

Use of carbon thin films, and in particular, diamond-like or diamond films, in semiconductor structures are desirable for several reasons. For example, diamond-like or diamond carbon films are relatively hard and inert and are thus well suited as a protective coatings. In addition, such carbon films are good conductors of heat; thus, carbon films can be used to form, for example, heat sinks. Furthermore, undoped carbon films are electrical insulators that exhibit very large break down voltages and may thus be used as dielectric films that form part of a semiconductor device. Also, when suitably doped, carbon forms a semiconductive material, with a relatively high band gap, that can be used to fabricated microelectronic devices. Carbon films are also transparent from the ultra-violet to the far infrared regions of the electromagnetic spectrum, and thus may be used to transmit light over a wide range of wavelengths.

For many years, attempts have been made to grow thin films of diamond on a foreign substrate. Attempts have been made, for example, to grow various monocrystalline layers of carbon on a substrate such as diamond or refractory metals such as nickel or molybdenum.

If a large area thin film of high quality diamond or diamond-like material was available at low cost, a variety of semiconductor devices could advantageously be fabricated in or using that film at a low cost compared to the cost of fabricating such devices beginning with a bulk wafer of diamond or in an epitaxial film of such material on a bulk substrate of nickel or molybdenum. In addition, if a thin film of high quality diamond or diamond-like material could be realized beginning with a bulk wafer such as a silicon wafer, an integrated device structure could be achieved that took advantage of the best properties of both the silicon and the high quality carbon material layer.

Accordingly, a need exists for a semiconductor structure that provides a high quality carbon film or layer over another monocrystalline material and for a process for making such a structure.

### BRIEF DESCRIPTION OF THE DRAWINGS

The present invention is illustrated by way of example and not limitation in the accompanying figures, in which like references indicate similar elements, and in which:

FIGS. 1 and 2 illustrate schematically, in cross section, device structures in accordance with various embodiments of the invention;

FIG. 3 illustrates graphically the relationship between maximum attainable film thickness and lattice mismatch between a host crystal and a grown crystalline overlayer; and

FIGS. 4 and 5 illustrate schematically, in cross-section, structures including devices formed using a carbon layer in accordance with the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 100 in accordance with an embodiment of the invention. Semiconductor structure 100 includes a monocrystalline substrate 102, an accommodating buffer layer 104 comprising a monocrystalline material, a graded layer 106, and a carbon layer 108. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 100 also includes an amorphous intermediate layer 110 positioned between substrate 102 and accommodating buffer layer 104. Structure 100 may also include a template layer 112 between the accommodating buffer layer and graded layer 106 and/or a template layer 114 between graded layer 106 and carbon layer 108. As will be explained more fully below, the template layers help to initiate the growth of the subsequently grown monocrystalline material. The amorphous intermediate layer helps to relieve the strain in the accommodating buffer layer, and by doing so, aids in the growth of a high crystalline quality accommodating buffer layer.

Substrate 102, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 102 is a wafer containing silicon or germanium, and most preferably is a high quality monocrystalline silicon wafer as used in the semiconductor industry. Accommodating buffer layer 104 is preferably a monocrystalline oxide or nitride material epitaxially grown on the underlying substrate. In accordance with one embodiment of the invention, amorphous intermediate layer 110 is grown on substrate 102 at the interface between substrate 102 and the growing accommodating buffer layer by the oxidation of substrate 102 during the growth of layer 104. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in subsequently formed films (e.g., layers 106 and 108).

Accommodating buffer layer 104 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxides or nitrides typically include at least two different metallic elements. In some specific applications, the metal oxides or nitrides may include three or more different metallic elements.

Amorphous interface layer 110 is preferably an oxide formed by the oxidation of the surface of substrate 102, and more preferably is composed of a silicon oxide. The thickness of layer 110 is sufficient to relieve strain attributed to mismatches between the lattice constants of substrate 102 and accommodating buffer layer 104. Typically, layer 110 has a thickness in the range of approximately 0.5-5 nm.

Graded layer 106 is configured such that the lattice constant of the layer varies with the thickness of the layer. For example, a composition of layer 106 can be manipulated such that a lower portion of layer 106 is substantially lattice matched to accommodating buffer layer 104 and an upper portion of layer 106 is substantially lattice matched to layer 108. In accordance with one embodiment of the invention, layer 106 comprises nickel aluminum (NiₓAl₁₋ₓ, where x ranges from 0 to 1), an more particularly, where x is 0 at a bottom surface of layer 106 and 1 near the top of layer 106. Other suitable graded layers comprise AlₓMo₁₋ₓ and AlₓIr₁₋ₓ, where x ranges from 0 to 1.

Layer 108 is formed of carbon, and is preferably formed of carbon having a diamond or diamond-like structure. In this context, diamond-like material shall mean material having a gram atom number density greater than 0.2 g-atom/cm³. Layer 108 thickness may vary from application to application. For example, when layer 108 is used to form semiconductor devices, layer 108 thickness may range from 50 nm to 5000 nm.

Appropriate materials for templates 112 and 114 are discussed below. Suitable template materials chemically bond to the surface of an underlying layer at selected sites and provide sites for the nucleation of the subsequent epitaxial growth of monocrystalline material. When used, template layers 112 and 114 have a thickness ranging from about 1 to about 10 monolayers.

FIG. 2 schematically illustrates, in cross section, a portion of a semiconductor structure 200 in accordance with another exemplary embodiment of the invention. Structure 200 is similar to structure 100, except that structure 200 includes an amorphous layer 202, rather than accommodating buffer layer 104 and amorphous interface layer 110.

As explained in greater detail below, amorphous layer 202 may be formed by first forming an accommodating buffer layer and an amorphous interface layer in a similar manner to that described above. Monocrystalline layer 112 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 202 formed in this manner comprises materials from both the accommodating buffer and interface layers, which amorphous layers may or may not amalgamate. Thus, layer 202 may comprise one or two amorphous layers. Formation of amorphous layer 202 between substrate 102 and layer 106 (subsequent to layer 112 formation) relieves stresses between layers 102 and 112 and provides a true compliant substrate for subsequent processing—e.g., monocrystalline material layer 106 formation.

The processes previously described above in connection with FIG. 1 is adequate for growing monocrystalline material layers over a monocrystalline substrate. However, the process described in connection with FIG. 2, which includes transforming a monocrystalline accommodating buffer layer to an amorphous oxide layer, may be better for growing monocrystalline material layers because it allows any strain in layer 112 to relax.

In accordance with one embodiment of the present invention, layer 112 serves as an anneal cap during layer 202 formation. Accordingly, layer 112 is preferably thick enough to provide a suitable template for layer 106 growth (at least one monolayer) and thin enough to allow layer 112 to form as a substantially defect free monocrystalline material. Alternatively, layer 106 may be formed before the structure is exposed to an anneal process designed to form layer 202.

The following non-limiting, illustrative examples illustrate various combinations of materials useful in structures 100 and 200 in accordance with various alternative embodiments of the invention. These examples are merely illustrative, and it is not intended that the invention be limited to these illustrative examples.

### EXAMPLE 1

In accordance with one embodiment of the invention, monocrystalline substrate 102 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 104 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 106. The accommodating buffer layer can have a thickness of about 2 to about 100 nanometers (nm) and preferably has a thickness of about 5 nm. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, graded layer 106 is a nickel-aluminum layer having a thickness of about 10 Å to about 50 Å. To facilitate the epitaxial growth of the graded on the monocrystalline oxide, a template layer is formed.

In accordance with one embodiment of the invention, the template includes a surfactant that comprises, but is not limited to, elements such as Al, In and Ga. In one exemplary embodiment, Al is used for the surfactant and functions to modify the surface and surface energy of layer 112. Preferably, the surfactant layer is epitaxially grown, to a thickness of one to two monolayers. The surfactant increases the surface energy of the monocrystalline oxide layer and also shifts the crystalline structure of the template to a diamond-like sp³ structure.

Layer 114 is configured to facilitate growth of monocrystalline or diamond-like carbon comprising layer 108. In accordance with one embodiment of the invention, layer 114 includes Face Cubic Centered (FCC) nickel epitaxially formed above graded layer 106. Layer 114 is preferably about 1 to about 10 monolayers thick.

Once layer 114 is formed, diamond or diamond-like carbon layer 108 is grown to a desired thickness. In accordance with one aspect of this embodiment, layer 108 includes up to a 5000 nm thick diamond film, doped with about 10¹⁷ to about 10¹⁸ atoms/cm³ of either a p-type dopant (e.g., boron) or an n-type dopant (e.g., phosphorous) to form a semiconductive diamond layer.

### EXAMPLE 2

This example provides exemplary materials useful in structure 200, as illustrated in FIG. 2. Substrate material 102, template layer 112, layer 106, layer 114, and layer 108 may be the same as those described above in connection with example 1.

Amorphous layer 202 is an amorphous oxide layer which is suitably formed of a combination of amorphous intermediate layer materials (e.g., layer 110 materials as described above) and accommodating buffer layer materials (e.g., layer 104 materials as described above). For example, amorphous layer 202 may include a combination of SiO_{X} and Sr_{z}Ba_{1-z}TiO₃ (where z ranges from 0 to 1), which may combine or mix during an anneal process to form amorphous oxide layer 202.

The thickness of amorphous layer 202 may vary from application to application and may depend on such factors as desired insulating properties of layer 202, type of device formed using layer 106, and the like. In accordance with one exemplary aspect of the present embodiment, layer 202 thickness is about 2 nm to about 100 nm, preferably about 2-10 nm, and more preferably about 5-6 nm.

Referring again to FIGS. 1-2, substrate 102 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 104 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

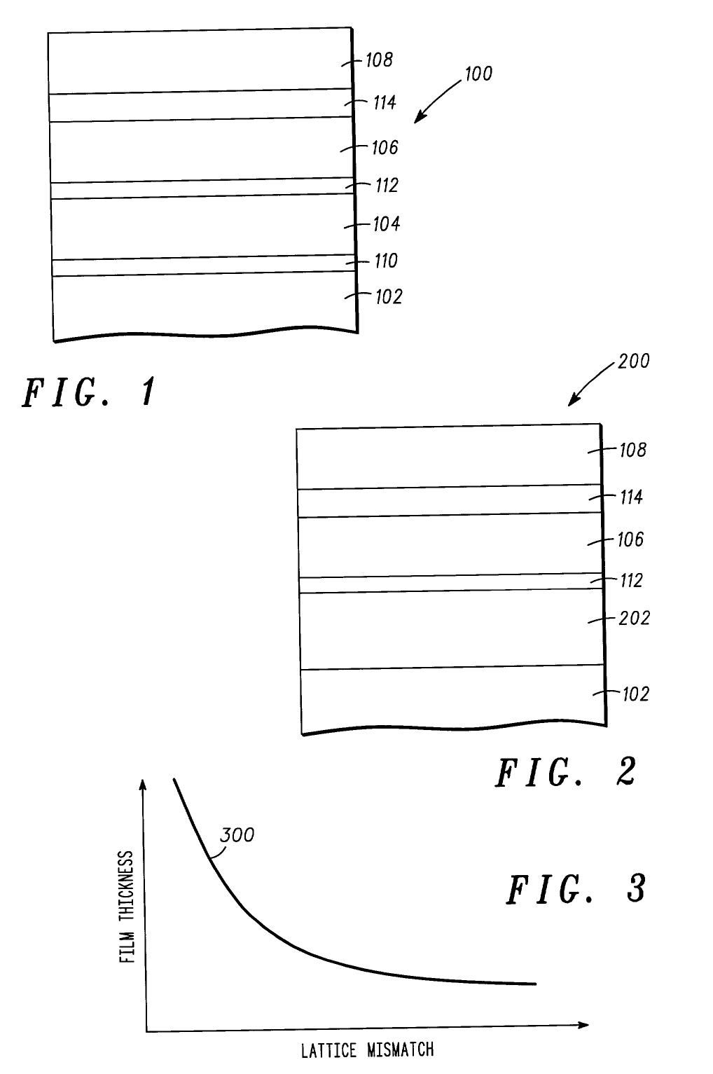

FIG. 3 illustrates graphically the relationship of the achievable thickness of a grown crystal layer of high crystalline quality as a function of the mismatch between the lattice constants of the host crystal and the grown crystal. Curve 300 illustrates the boundary of high crystalline quality material. The area to the right of curve 300 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 102 is a (100) or (111) oriented monocrystalline silicon wafer and accommodating buffer layer 104 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 110, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-2, layer 106 is a layer of epitaxially grown monocrystalline material and the bottom layer of that crystalline material is also characterized by a crystal lattice constant and a crystal orientation. In accordance with one embodiment of the invention, the lattice constant of the bottom of layer 106 differs from the lattice constant of substrate 102. To achieve high crystalline quality in this epitaxially grown monocrystalline layer, the accommodating buffer layer must be of high crystalline quality. In addition, in order to achieve high crystalline quality in layer 106, substantial matching between the crystal lattice constant of the host crystal, in this case, the monocrystalline accommodating buffer layer, and the grown crystal is desired.

Finally, as noted above, layer 108, when layer 108 comprises diamond, is also characterized by a lattice constant and that lattice constant differs from the lattice constant of the bottom portion of layer 106. However, if layer 106 is properly graded, the lattice constant of the top portion of layer 106 is substantially matched to the lattice constant of carbon layer 108. Thus, high quality diamond films can be grown overlying layer 106.

The following example illustrates a process, in accordance with one embodiment of the invention, for fabricating a semiconductor structure such as the structures depicted in FIGS. 1-2. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis toward [110]. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkali earth metals or combinations of alkali earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkali earth metal oxide, such as strontium oxide, strontium barium oxide, or barium oxide, onto the substrate surface by MBE at a low temperature and by subsequently heating the structure to a temperature of about 850° C. At this temperature, a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stochiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered monocrystal with the crystalline orientation rotated by 45° with respect to the ordered 2×1 crystalline structure of the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a graded material layer. For example, for the subsequent growth nickel aluminum, the MBE growth of the strontium titanate monocrystalline layer can be capped by terminating the growth with 1-2 monolayers of titanium, 1-2 monolayers of titanium-oxygen or with 1-2 monolayers of strontium-oxygen.

As noted above, the template layer may also include a surfactant. In this case, 1-2 monolayers of surfactant such as aluminum are deposited using, for example, MBE.

Following the formation of the template layer, graded layer 106 is formed by introducing nickel and aluminum into the reaction chamber. Initially, the ratio of nickel to aluminum is near 0:1, and the ratio varies along the thickness of the film to about 1:0, such that the top of layer 106 is formed of nickel.

A thin layer 114 of nickel may then be formed above graded layer. Layer 114 serves as a template for diamond or diamond-like carbon growth of layer 108.

In accordance with one embodiment of the invention, layer 108 is formed using, for example, gas-source molecular beam epitaxy (GSMBE) using a suitable carbon source such as methane.

Structure 200, illustrated in FIG. 2, may be formed by growing an accommodating buffer layer, forming an amorphous oxide layer over substrate 102, and forming layer 112 and/or layer 106 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 202. In accordance with one embodiment of the invention, layer 106 is then subsequently grown over layer 112. Alternatively, the anneal process may be carried out subsequent to growth of layer 106.

In accordance with one aspect of this embodiment, layer 202 is formed by exposing substrate 102, the accommodating buffer layer, and the amorphous oxide layer to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 202. When conventional thermal annealing is employed to form layer 202, an overpressure of one or more constituents of layer 112 or layer 106 may be required to prevent degradation of layer 112 or 106 during the anneal process.

The process described above illustrates a process for forming a semiconductor structure including a silicon substrate, an overlying oxide layer, a graded layer, and a carbon layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), the like, or any combination of such processes. Further, by a similar process, other monocrystalline accommodating buffer layers such as alkaline earth metal titanates, zirconates, hafnates, tantalates, vanadates, ruthenates, and niobates, peroskite oxides such as alkaline earth metal tin-based perovskites, lanthanum aluminate, lanthanum scandium oxide, and gadolinium oxide can also be grown.

FIG. 4 illustrates schematically, in cross section, a device structure 400 in accordance with a further embodiment of the invention. Device structure 400 includes a monocrystalline semiconductor substrate 402, preferably a monocrystalline silicon wafer. Monocrystalline semiconductor substrate 402 includes two regions, 404 and 406. An electrical semiconductor component generally indicated by the dashed line 408 is formed, at least partially, in region 404. Electrical component 408 can be a resistor, a capacitor, an active semiconductor component such as a diode or a transistor or an integrated circuit such as a CMOS integrated circuit. For example, electrical semiconductor component 408 can be a CMOS integrated circuit configured to perform digital signal processing or another function for which silicon integrated circuits are well suited. The electrical semiconductor component in region 404 can be formed by conventional semiconductor processing as is well known and widely practiced in the semiconductor industry. A layer of insulating material 410 such as a layer of silicon oxide or the like may overlie electrical semiconductor component 408.

Insulating material 410 and any other layers that may have been formed or deposited during the processing of semiconductor component 408 in region 404 are removed from the surface of region 406 to provide a bare silicon surface in that region. As is well known, bare silicon surfaces are highly reactive and a native silicon oxide layer can quickly form on the bare surface. A layer of strontium or strontium and oxygen is deposited onto the native oxide layer on the surface of region 406 and is reacted with the oxidized surface to form a first template layer (not shown). In accordance with one embodiment of the invention a monocrystalline oxide layer is formed overlying the template layer by a process of molecular beam epitaxy. Reactants including strontium, titanium and oxygen are deposited onto the template layer to form the monocrystalline oxide layer. During the deposition, the partial pressure of oxygen is initially set near the minimum necessary to fully react with the strontium and titanium to form the monocrystalline strontium titanate layer. As the monocrystalline oxide forms, the partial pressure of oxygen is increased to form an amorphous layer between the growing crystalline layer and the substrate.

In accordance with an embodiment of the invention, the step of depositing the monocrystalline oxide layer is terminated by forming a layer 412, which includes 1-10 monolayers of titanium, barium, strontium, barium and oxygen, titanium and oxygen, or strontium and oxygen, and may additionally include a surfactant (e.g, 1-2 monolayers of Al) and/or a cap layer.

In accordance with one aspect of the present embodiment, after layer 412 formation, the monocrystalline titanate layer is exposed to an anneal process such that the titanate layer forms an amorphous oxide layer 414. A monocrystalline graded layer 416, a nickel template layer 418, a monocrystalline carbon layer 420 are then epitaxially grown over layer 412, using the techniques described above. Layer 420 is suitably doped with p-type or n-type dopants to form a semiconductive layer 420.

In accordance with a further embodiment of the invention, a semiconductor component, generally indicated by a dashed line 422 is formed, at least partially, in layer 420, which is formed of doped diamond carbon. Semiconductor component 422 can be formed by processing steps conventionally used in the fabrication of semiconductor material devices. Semiconductor component 422 can be any active or passive component or another component that utilizes and takes advantage of the physical properties of carbon material layers. A metallic conductor schematically indicated by the line 424 can be formed to electrically couple device 408 and device 422, thus implementing an integrated device that includes at least one component formed in the silicon substrate and one device formed in the monocrystalline carbon layer.

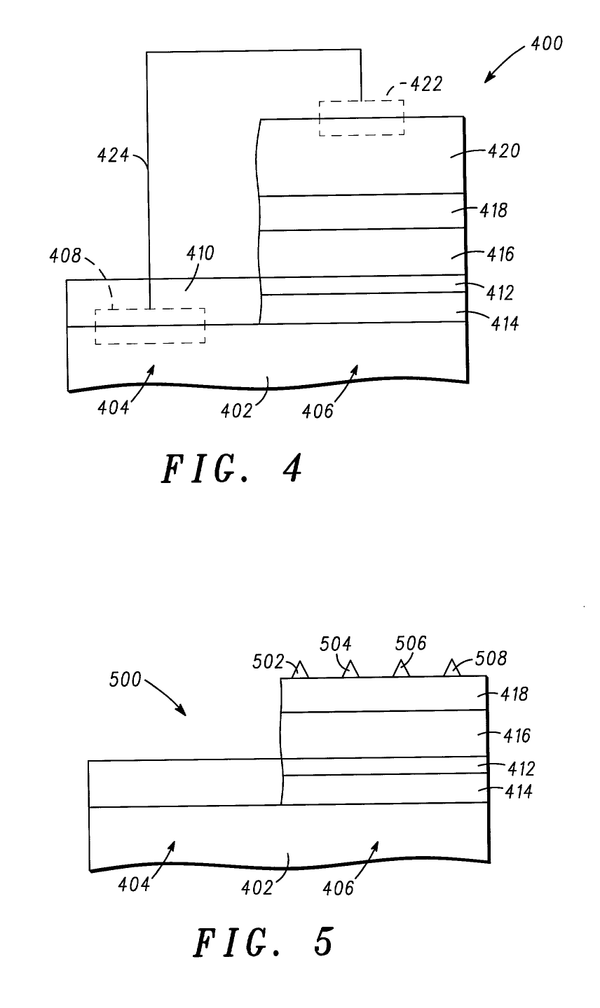

Although illustrative structure 400 has been described as a structure formed on a silicon substrate 402 and having a strontium (or barium) titanate layer, similar devices can be fabricated using other monocrystalline substrates, oxide layers and other monocrystalline material layers as described elsewhere in this disclosure. FIG. 5 illustrates a structure 500, suitable for forming field emission devices, in accordance with another embodiment of the invention. Structure 500 is similar to structure 400, except that a carbon layer 420 is replaced by carbon structure 502, 504, 506, and 508.

In accordance with a preferred aspect of this embodiment, structures 502-508 are formed of diamond-like carbon, rather than diamond. Structures 502-508 may be formed by pattering a surface of layer 418 with a suitable mask such as silicon nitride and depositing the carbon through the openings of the mask onto layer 418. Alternatively, a layer of diamond-like carbon may be formed overlying layer 418, and the carbon layer may be suitably masked and etched to form structures 502-508.

Clearly, those embodiments specifically describing structures having carbon portions and Group IV semiconductor portions are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and insulating layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include carbon layers as well as other material layers that are used to form those devices with other components that work better or are easily and/or inexpensively formed. This allows a device to be shrunk, the manufacturing costs to decrease, and yield and reliability to increase.

In accordance with one embodiment of this invention, a monocrystalline semiconductor or compound semiconductor wafer can be used in forming carbon layers over the wafer. In this manner, the wafer is essentially a “handle” wafer used during the fabrication of carbon-based electrical components. Therefore, electrical components can be formed using carbon materials over a wafer of at least approximately 200 millimeters in diameter and possibly at least approximately 300 millimeters.

By the use of this type of substrate, fabrication costs for carbon-based devices should decrease because larger substrates can be processed more economically and more readily compared to the relatively smaller substrates (e.g. conventional substrates used to form carbon films).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not necessarily include only those elements but may include other elements not expressly listed or inherent to such process, method, article, or apparatus.

We claim:

1. A semiconductor structure comprising:
a monocrystalline substrate;
an accommodating buffer layer formed on the substrate;
a first template formed above the accommodating buffer layer; and
a carbon formed overlying the first template.

2. The semiconductor structure of claim 1, wherein the carbon layer comprises diamond-like carbon.

3. The semiconductor structure of claim 1, wherein the carbon layer comprises diamond material.

4. The semiconductor structure of claim 1, further comprising a graded layer interposed between the accommodating buffer layer and the first template layer.

5. The semiconductor structure of claim 4, wherein the graded layer comprises a material selected from the croup consisting of NiₓAl₁₋ₓ, AlₓMo₁₋ₓ, and AlₓIr₁₋ₓ, where x ranges from 0 to 1.

6. The semiconductor structure of claim 5, wherein the graded layer has an upper surface and a lower surface, and the value of x ranges from about 0 at a lower surface to about 1 at an upper surface.

7. The semiconductor structure of claim 4, further comprising a second template layer interposed between the accommodating buffer layer and the graded layer.

8. The semiconductor structure of claim 7, wherein the second template includes a surfactant.

9. The semiconductor structure of claim 8, wherein the surfactant is selected from the group consisting of aluminum, indium, and gallium.

10. The semiconductor structure of claim 7, wherein the second template includes a cap layer.

11. The semiconductor structure of claim 1, wherein the accommodating buffer layer is monocrystalline.

12. The semiconductor structure of claim 11, further comprising an amorphous interface layer interposed between the monocrystalline substrate and the accommodating buffer layer.

13. The semiconductor structure of claim 1, wherein the accommodating buffer layer is amorphous.

14. The semiconductor structure of claim 1, wherein the accommodating buffer layer comprises an oxide selected from the group consisting of alkaline earth metal titanates, alkaline earth metal zirconates, alkaline earth metal hafniates, alkaline earth metal tantalates, alkaline earth metal ruthenates, and alkaline earth metal niobates.

15. The semiconductor structure of claim 14, wherein the accommodating buffer layer comprises SrₓBa₁₋ₓTiO₃, where x ranges from 0 to 1.

16. The semiconductor structure of claim 1, wherein the accommodating buffer layer comprises an oxide formed as a monocrystalline oxide and subsequently heat treated to convert the monocrystalline oxide to an amorphous oxide.

17. The semiconductor structure of claim 1, wherein the monocrystalline substrate comprises silicon.

18. The semiconductor structure of claim 1, wherein the accommodating buffer layer has a thickness of about 2-10 nm.

19. The semiconductor structure of claim 1, wherein the carbon layer is doped with about 10¹⁷ to about 10¹⁸ atoms per cubic centimeter of a p-type dopant.

20. The semiconductor structure of claim 19, wherein the p-type dopant is boron.

21. The semiconductor structure of claim 1, wherein the carbon layer is doped with about 10¹⁷ to about 10¹⁸ atoms per cubic centimeter of an n-type dopant.

22. The semiconductor structure of claim 21, wherein the n-type dopant is phosphorous.

23. The semiconductor structure of claim 1, further comprising a microelectronic device formed using the carbon layer.

24. The semiconductor structure of claim 1, further comprising a microelectronic device formed using the monocrystalline substrate.

25. A process for fabricating a semiconductor structure comprising the steps of:
providing a monocrystalline semiconductor substrate;
epitaxially growing a monocrystalline accommodating buffer layer overlying the monocrystalline semiconductor substrate;
forming a first amorphous layer between the monocrystalline semiconductor substrate and the monocrystalline accommodating buffer layer during the step of epitaxially growing;
forming a carbon layer above the monocrystalline accommodating buffer layer.

26. The process of claim 25, further comprising the step of annealing the monocrystalline accommodating buffer layer to form an amorphous accommodating buffer layer.

27. The process of claim 25, further comprising the step of forming a first template layer on the monocrystalline accommodating buffer layer.

28. The process of claim 27, wherein the step of forming a first template includes forming a layer comprising aluminum.

29. The process of claim 27, further comprising the step of forming a graded layer overlying the first template.

30. The process of claim 29, wherein the step of forming a graded layer includes epitaxially growing a layer comprising a material selected from the croup consisting of NiₓAl₁₋ₓ, AlₓMo₁₋ₓ, and AlₓIr₁₋ₓ, where x ranges from 0 to 1.

31. The process of claim 29, further comprising the step of forming a second template layer overlying the graded layer.

32. The process of claim 31, wherein the step of forming a second template layer includes forming a layer of nickel.

33. The process of claim 25, wherein the step of forming a carbon layer includes forming a layer of diamond-like carbon.

34. The process of claim 25, wherein the step of forming a carbon layer includes forming a layer of diamond.

35. The process of claim 25, further comprising the step of forming a microelectronic device using the carbon layer.

36. The process of claim 25, further comprising the step of forming a microelectronic device using the monocrystalline semiconductor substrate.

37. An integrated circuit comprising:
a substrate;
an accommodating buffer layer overlying the substrate;
a carbon layer overlying the accommodating buffer layer; and
a microelectronic device formed using the carbon layer.

38. The integrated circuit of claim 37, wherein the microelectronic device includes a field emission device.

39. The integrated circuit of claim 37, wherein the microelectronic device includes a semiconductor device.

40. The integrated circuit of claim 37, farther comprising a graded layer interposed between the accommodating buffer layer and the carbon layer.

41. The integrated circuit of claim 37, further comprising a microelectronic device formed using the substrate.
